(19) United States
(12) Patent Application Publication
(10) Pub. No.: US 2023/0122600 A1
(43) Pub. Date: Apr. 20, 2023

(54) PHOTOSENSITIVE RESIN COMPOSITION, PHOTOSENSITIVE RESIN FILM PREPARED USING SAME, AND DISPLAY DEVICE

(71) Applicant: SAMSUNG SDI CO., LTD., Yongin-si, Gyeonggi-do (KR)

(72) Inventors: Kwangseop KIM, Suwon-si, Gyeonggi-do (KR); Arum YU, Suwon-si, Gyeonggi-do (KR); Heekyoung KANG, Suwon-si, Gyeonggi-do (KR); Taesoo KIM, Suwon-si, Gyeonggi-do (KR); Myungho CHO, Suwon-si, Gyeonggi-do (KR)

(21) Appl. No.: 17/910,398

(22) PCT Filed: Mar. 16, 2021
(86) PCT No.: PCT/KR2021/003205

§ 371 Date: Sep. 9, 2022

(30) Foreign Application Priority Data
Mar. 18, 2020 (KR) 10-2020-0033356
Mar. 3, 2021 (KR) 10-2021-0028255

(51) Int. Cl. G03F 7/032; G03F 7/00; G03F 7/004

(52) U.S. Cl. CPC G03F 7/032; G03F 7/0007; G03F 7/0048; G03F 7/0043

(57) ABSTRACT

Provided are a photosensitive resin composition including (A) a binder resin including a first binder resin and a second binder resin, (B) a photopolymerizable monomer, (C) a photopolymerization initiator, (D) a black inorganic pigment, (E) an inorganic scatterer, and (F) a solvent, wherein the first binder resin has a higher refractive index than the second binder resin, the first binder resin is included in an amount equal to or less than that of the second binder resin, and a primary particle diameter of the black inorganic pigment is less than or equal to 45 nm, a photosensitive resin layer using the same, and a display device including the photosensitive resin layer.

### TECHNICAL FIELD

This disclosure relates to a photosensitive resin composition, a photosensitive resin layer using the same, and a display device including the photosensitive resin layer.

### BACKGROUND ART

A black photosensitive resin composition is necessarily used to fabricate a display element for a color filter, a liquid crystal display material, an organic light emitting element (EL), a display panel material, and the like. For example, a color filter such as a color liquid crystal display and the like needs a black matrix or light blocking partition wall on the border between colored layers such as red, green, blue, and the like to enhance display contrast or chromophore effects. The black matrix or light blocking partition wall may be mainly formed of a black photosensitive resin composition.

In particular, recent development of a liquid crystal display has been geared to high luminance and high color reproducibility, and in order to achieve these properties, there has been an attempt to reduce reflectance of light coming from outdoors. In order to reduce reflectance of a display, a method of applying an anti-reflection film of a polarization film, an AR (Anti Reflective) film and an AG (Anti Glare) film, is mainly developed.

However, since this method now reaches a limit as well as costs high, there are ongoing efforts to reduce the reflectance in other ways.

### DISCLOSURE

### Technical Problem

An embodiment is to provide a photosensitive resin composition having excellent surface roughness and linearity of a pattern while simultaneously implementing light blocking characteristics and low-reflection characteristics.

Another embodiment is to provide a photosensitive resin layer manufactured using the photosensitive resin composition.

Another embodiment is to provide a display device including the photosensitive resin layer.

### Technical Solution

An embodiment provides a photosensitive resin composition including (A) a binder resin including a first binder resin and a second binder resin, (B) a photopolymerizable monomer, (C) a photopolymerization initiator, (D) a black inorganic pigment, (E) an inorganic scatterer, and (F) a solvent, wherein the first binder resin has a higher refractive index than the second binder resin, the first binder resin is included in an amount equal to or less than that of the second binder resin, and a primary particle diameter of the black inorganic pigment is less than or equal to 45 nm.

The second binder resin may have a refractive index of less than or equal to 1.55.

The first binder resin may be a cardo-based binder resin and the second binder resin may be an acryl-based binder resin.

An amount of the second binder resin may be at least twice an amount of the first binder resin.

The primary particle diameter of the black inorganic pigment may be less than or equal to 30 nm.

The black inorganic pigment may include carbon black.

The inorganic scatterer may include SiO₂, TiO₂, ZrO₂, BaSO₃, or a combination thereof.

Both the black inorganic pigment and the inorganic scatterer may be included in a form of a dispersion, and an amount of the dispersion including black inorganic pigment may be 3 times or more of an amount of the dispersion including the inorganic scatterer.

The photosensitive resin composition may further include a dye.

The dye may include a red dye, a yellow dye, a violet dye, or a combination thereof.

The dye may be included in an amount less than that of the dispersion including black inorganic pigment.

The photosensitive resin composition, based on a total amount of the photosensitive resin composition, may include 1 wt % to 10 wt % of the (A) binder resin, 0.5 wt % to 5 wt % of the (B) photopolymerizable monomer, 0.1 wt % to 5 wt % of the (C) photopolymerization initiator, 5 wt % to 10 wt % of the (D) black inorganic pigment, 0.01 wt % to 0.1 wt % of the (E) inorganic scatterer, and 30 wt % to 70 wt % of the (F) solvent.

The photosensitive resin composition may further include malonic acid, 3-amino-1,2-propanediol, a silane-based coupling agent, a leveling agent, a surfactant, or a combination thereof.

Another embodiment provides a photosensitive resin layer manufactured using the photosensitive resin composition.

The photosensitive resin layer may be a black matrix or light blocking partition wall.

Another embodiment provides a display device including the photosensitive resin layer.

Other embodiments of the present invention are included in the following detailed description.

### Advantageous Effects

The photosensitive resin composition according to an embodiment uses two types of binder resins having different refractive indices in each certain amount, limiting their amounts, and by using a black inorganic pigment having a primary particle diameter in a certain range together, light blocking properties and low-reflection characteristics may be simultaneously implemented, patternability may be maintained excellently.

### DESCRIPTION OF DRAWINGS

FIG. 1 is a scanning electron microscopic photograph showing a pattern photograph of a photosensitive resin layer manufactured by using the photosensitive resin composition according to Example 1.

FIG. 2 is a scanning electron microscopic photograph showing a pattern photograph of a photosensitive resin layer manufactured by using the photosensitive resin composition according to Example 2.

FIG. 3 is a scanning electron microscopic photograph showing a pattern photograph of a photosensitive resin layer manufactured by using the photosensitive resin composition according to Comparative Example 1.

FIG. 4 is a scanning electron microscopic photograph showing a pattern photograph of a photosensitive resin layer manufactured by using the photosensitive resin composition according to Comparative Example 2.

FIG. 5 is a scanning electron microscopic photograph showing a pattern photograph of a photosensitive resin layer manufactured by using the photosensitive resin composition according to Comparative Example 3.

FIG. 6 is a scanning electron microscopic photograph showing a pattern photograph of a photosensitive resin layer manufactured by using the photosensitive resin composition according to Reference Example 1.

### BEST MODE

Hereinafter, embodiments of the present invention are described in detail. However, these embodiments are exemplary, the present invention is not limited thereto and the present invention is defined by the scope of claims.

In the present specification, when specific definition is not otherwise provided, “alkyl group” refers to a C1 to C20 alkyl group, “alkenyl group” refers to a C2 to C20 alkenyl group, “cycloalkenyl group” refers to a C3 to C20 cycloalkenyl group, “heterocycloalkenyl group” refers to a C3 to C20 heterocycloalkenyl group, “aryl group” refers to a C6 to C20 aryl group, “arylalkyl group” refers to a C6 to C20 arylalkyl group, “alkylene group” refers to a C1 to C20 alkylene group, “arylene group” refers to a C6 to C20 arylene group, “alkylarylene group” refers to a C6 to C20 alkylarylene group, “heteroarylene group” refers to a C3 to C20 heteroarylene group, and “alkoxylene group” refers to a C1 to C20 alkoxylene group.

In the present specification, when specific definition is not otherwise provided, “substituted” refers to replacement of at least one hydrogen by a substituent of a halogen atom (F, Cl, Br, or I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof.

In the present specification, when specific definition is not otherwise provided, “hetero” refers to one including at least one heteroatom selected from N, O, S and P in chemical formula.

In the present specification, when specific definition is not otherwise provided, “(meth)acrylate” refers to both “acrylate” and “methacrylate”, and “(meth)acrylic acid” refers to “acrylic acid” and “methacrylic acid”.

In the present specification when a definition is not otherwise provided, “combination” refers to mixing or copolymerization. Also, “copolymerization” refers to block copolymerization or random copolymerization, and “copolymer” refers to a block copolymer or a random copolymer.

In the present specification, when a definition is not otherwise provided, hydrogen is bonded at the position when a chemical bond in chemical formulae is not drawn where supposed to be given.

In the present specification, a cardo-based resin refers to a resin including at least one functional group selected from Chemical Formula 2 to Chemical Formula 12 in its backbone.

In the present specification, when a definition is not otherwise provided, “*” indicates a point where the same or different atom (including a hydrogen atom) or chemical formula is linked.

Unless otherwise defined herein, the refractive index means the refractive index at a wavelength of 550 nm.

A photosensitive resin composition according to an embodiment includes (A) a binder resin including a first binder resin and a second binder resin, (B) a photopolymerizable monomer, (C) a photopolymerization initiator, (D) a black inorganic pigment, (E) an inorganic scatterer, and (F) a solvent, wherein the first binder resin has a higher refractive index than the second binder resin, the first binder resin is included in an amount equal to or less than that of the second binder resin, and the inorganic pigment has a primary particle diameter of less than or equal to 45 nm, and thus a photosensitive resin layer using the same, for example a black matrix or a light blocking partition wall may implement both light blocking properties and low-reflection characteristics and may have improved patternability (pattern surface roughness, pattern linearity, etc.) compared with a conventional black matrix or light blocking partition wall.

Specifically, the photosensitive resin composition according to an embodiment is applied to a black matrix or a light blocking partition wall for distinguishing red, green, and blue colors in a color filter, but most of the conventional compositions for a black matrix or a light blocking partition wall include carbon black as a main component in order to accomplish effective light blocking characteristics. When the carbon black is used as a main component, the composition has high optical density and thus may be suitable for achieving the light blocking characteristics but has a problem of not improving visibility. In addition, when a relative amount of a black inorganic pigment such as the carbon black is increased, there is a problem of roughening a pattern surface or deteriorating pattern linearity, resolution, and the like, while when the relative amount of the carbon black is decreased, there is also a problem of decreasing light blocking and thus not securing minimum optical density within a general coating thickness (1 μm to 1.3 μm). Accordingly, the inventors of the present invention have recognized the aforementioned problems and developed a panel having a lower reflectance to improve visibility and thus have completed the present invention through several trials and errors. In fact, an attempt to attach a film (e.g., a low-reflective polarization film, etc.) in order to improve the reflectance has been made. However, since the polarization film is not only expensive, but the corresponding technology also reaches its bottom limit of realizing the reflectance and thereby exposes a limit of the current method of attaching additional films, development of a composition for manufacturing a black matrix or a light blocking partition wall, which may lower the reflectance in other ways, is being made. Particularly, since TV with 8K high resolution has about twice as large a surface area as that of TV with 4K, as the reflectance as well as the light blocking characteristics is lower, a greater effect of improving the visibility may be obtained.

Hereinafter, each component is described in detail.

(E) Inorganic Scatterer

The photosensitive resin composition according to an embodiment includes an inorganic scatterer, specifically, dispersion including the inorganic scatterer. Conventionally, there have been attempts to add the dispersion including the inorganic scatterer to a photosensitive resin composition, but when an amount of the dispersion including the inorganic scatterer is increased, amounts of other inorganic materials used along therewith also cannot but be increased as much, and thereby, a relative amount of a black colorant imparting light blocking characteristics (e.g., a black pigment and the like) is decreased and thus decreases optical density, not forming a black matrix or a light blocking partition wall.

However, the photosensitive resin composition according to an embodiment uses the dispersion including the inorganic scatterer but as described later, solves the aforementioned problem by using two types of binger resins having a different refractive index and limiting amounts of the two types of binder resins and simultaneously, further limiting a primary particle diameter of the black inorganic pigment working as the black colorant. In other words, the photosensitive resin composition according to an embodiment includes the dispersion including the inorganic scatterer but may have no optical density decrease problem.

For example, the inorganic scatterer may include SiO₂, TiO₂, ZrO₂, BaSO₃, or a combination thereof, but is not limited thereto.

For example, the inorganic scatterer may be included in an amount of greater than or equal to 1 wt % based on a total amount of solids constituting the photosensitive resin composition according to an embodiment. In this case, the photosensitive resin layer manufactured by using the photosensitive resin composition according to an embodiment may have an optical density (unit: /1 μm) of greater than or equal to 3.2.

For example, the dispersion including an inorganic scatterer may be included in an amount of 1 wt % to 10 wt %, for example 5 wt % to 10 wt %, based on a total amount of the photosensitive resin composition. (The inorganic scatterer may be included in an amount of 0.01 wt % to 0.1 wt % based on a total amount of the photosensitive resin composition.) When the dispersion including an inorganic scatterer is included in the above amount range, it may have excellent compatibility with the dispersion including black inorganic pigment and thus it is possible to secure light blocking properties simultaneously while maintaining low-reflection characteristics and excellent patternability.

(A) Binder Resin

The photosensitive resin composition according to an embodiment includes two types of binder resins having different refractive indices, and the binder resin (first binder resin) having a higher refractive index is included in an amount equal to or less than the binder resin (second binder resin) having a lower refractive index. If the binder resin does not have such a configuration, low-reflection characteristics may not be implemented.

Specifically, the second binder resin may have a refractive index of less than or equal to 1.55. For example, the first binder resin may have a refractive index of greater than or equal to 1.60.

For example, an amount of the second binder resin may be at least twice an amount of the first binder resin. In this case, developability and process margin may be improved.

For example, the first binder resin may be a cardo-based binder resin, and the second binder resin may be an acryl-based binder resin. In this case, heat resistance and chemical resistance of the photosensitive resin composition according to an embodiment may be improved, and above all, it may be very advantageous to secure low-reflection characteristics.

The weight average molecular weight of the cardo-based binder resin may be 1,000 g/mol to 50,000 g/mol, and specifically, 3,000 g/mol to 35,000 g/mol. When the weight average molecular weight of the cardo-based binder resin is within the above range, excellent patternability and developability may be obtained when manufacturing a black matrix or a light blocking partition wall.

The cardo-based binder resin may be a compound including a repeating unit represented by Chemical Formula 1.

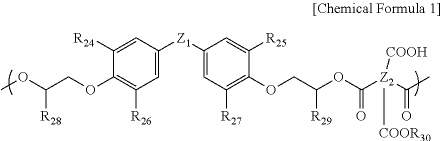

In Chemical Formula 1,

R₂₄ to R₂₇ may independently be a hydrogen atom, a halogen atom, or a substituted or unsubstituted C1 to C20 alkyl group,

R₂₈ and R₂₉ may independently be a hydrogen atom, or CH₂ORₐ (wherein Rₐ is a vinyl group, an acryl group, or a methacryl group),

R₃₀ may be a hydrogen atom, a substituted or unsubstituted C1 to C20 alkyl group, a substituted or unsubstituted C2 to C20 alkenyl group, an acryl group, or a methacryl group,

Z₁ may be a single bond, O, CO, SO₂, CR_{b}R_{c}, SiR_{d}Rₑ (wherein, R_{b} to Rₑ are the same or different, and may be a hydrogen atom, or a substituted or unsubstituted C1 to C20 alkyl group), or selected from one of compounds represented by Chemical Formula 2 to Chemical Formula 12, and

Z₂ may be an acid anhydride residual group or an acid dianhydride residual group.

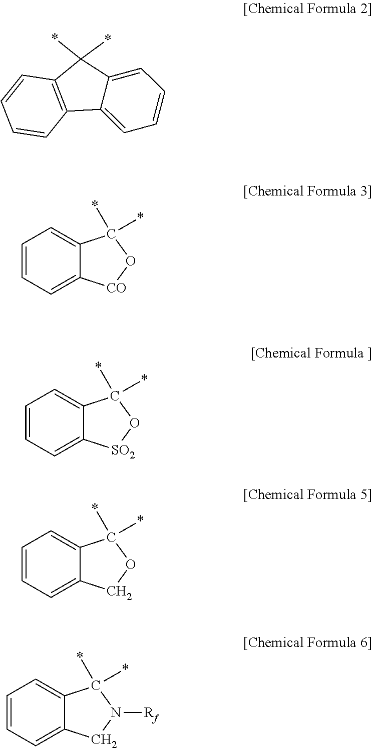

In Chemical Formula 6,

R_{f} is a hydrogen atom, an ethyl group, C₂H₄Cl, C₂H₄OH, CH₂CH═CH₂, or a phenyl group.

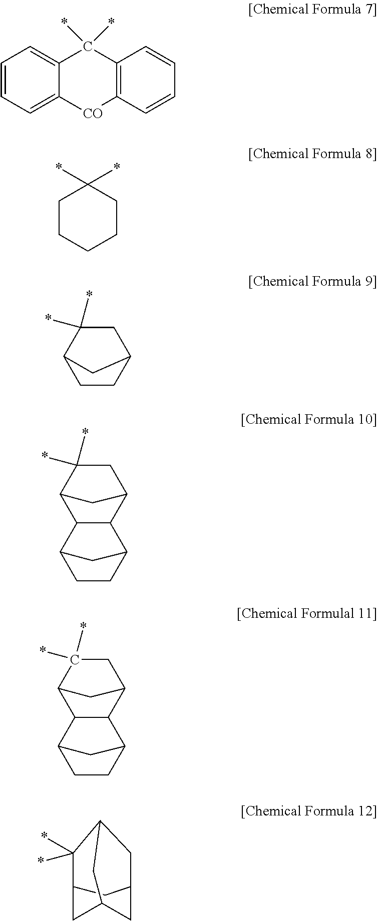

The cardo-based binder resin may be specifically obtained by reacting a compound represented by Chemical Formula 13 with a tetracarboxylic dianhydride.

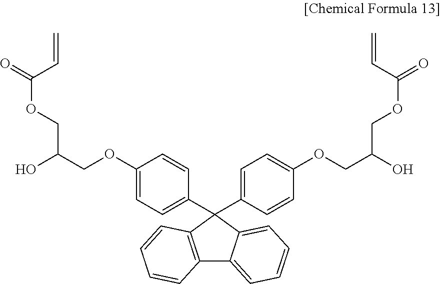 [SMILES: C=CC(=O)OCC(O)COc1ccc(C2(c3ccc(OCC(O)COC(=O)C=C)cc3)c3ccccc3-c3ccccc32)cc1]

The tetracarboxylic dianhydride may be an aromatic tetracarboxylic dianhydride. Examples of the aromatic tetracarboxylic dianhydride may include pyromellitic dianhydride, 3,3′,4,4′-biphenyltetracarboxylic dianhydride, 2,3,3′,4-biphenyltetracarboxylic dianhydride, 2,2′,3,3′-biphenyltetracarboxylic dianhydride, 3,3′,4,4′-benzophenonetetracarboxylic dianhydride, 3,3′,4,4′-biphenylethertetracarboxylic dianhydride, 3,3′,4,4′-diphenylsulfonetetracarboxylic dianhydride, 1,2,3,4-cyclopentanetetracarboxylic dianhydride, 1,2,5,6-naphthalenetetracarboxylic dianhydride, 2,3,6,7-naphthalenetetracarboxylic dianhydride, 1,4,5,8-naphthalenetetracarboxylic dianhydride, 2,3,5,6-pyridine tetracarboxylic dianhydride, 3,4,9,10-perylenetetracarboxylic dianhydride, 2,2-bis(3,4-dicarboxyphenyl) hexafluoropropane dianhydride, and the like, but are not limited thereto.

The acryl-based binder resin is a copolymer of a first ethylenically unsaturated monomer and a second ethylenically unsaturated monomer copolymerizable therewith, and is a resin including at least one acryl-based repeating unit.

The first ethylenically unsaturated monomer may be an ethylenically unsaturated monomer including one or more carboxyl groups, and specific examples thereof may include acrylic acid, methacrylic acid, maleic acid, itaconic acid, fumaric acid, or a combination thereof.

The first ethylenically unsaturated monomer may be included in an amount of 5 to 50 wt %, specifically 10 to 40 wt %, and specifically 10 to 40 weight % based on a total amount of the acryl-based binder resin.

The second ethylenically unsaturated monomer may include aromatic vinyl compounds such as styrene, α-methylstyrene, vinyltoluene, and vinylbenzylmethylether; unsaturated carboxylic acid ester compounds such as methyl (meth)acrylate, ethyl (meth)acrylate, butyl (meth)acrylate, 2-hydroxyethyl (meth)acrylate, 2-hydroxy butyl (meth)acrylate, benzyl (meth)acrylate, cyclohexyl (meth)acrylate and phenyl (meth)acrylate; unsaturated carboxylic acid amino alkyl ester compounds such as 2-aminoethyl (meth)acrylate and 2-dimethylaminoethyl (meth)acrylate; carboxylic acid vinyl ester compounds such as vinyl acetate and vinyl benzoate; unsaturated carboxylic acid glycidyl ester compounds such as glycidyl (meth)acrylate; vinyl cyanide compounds such as (meth)acrylonitrile; unsaturated amide compounds such as (meth)acrylamide; and the like, and these may be used alone or in combination of two or more.

Specific examples of the acryl-based binder resin may include a methacrylic acid/benzylmethacrylate copolymer, a methacrylic acid/benzylmethacrylate/styrene copolymer, a methacrylic acid/benzylmethacrylate/2-hydroxyethylmethacrylate copolymer, a methacrylic acid/benzylmethacrylate/styrene/2-hydroxyethylmethacrylate copolymer, but are not limited thereto, and these may be used alone or in combination of two or more.

The acryl-based binder resin may have a weight average molecular weight of 3,000 g/mol to 150,000 g/mol, specifically, 5,000 g/mol to 50,000 g/mol, and more specifically, 20,000 g/mol to 30,000 g/mol. When the weight average molecular weight of the acryl-based binder resin is within the above range, the physical and chemical properties of the photosensitive resin composition according to an embodiment are improved, the viscosity is appropriate, and a close contacting property to the substrate is improved when manufacturing a black matrix or a light blocking partition wall.

The acryl-based binder resin may have an acid value of 15 mgKOH/g to 60 mgKOH/g, and specifically 20 mgKOH/g to 50 mgKOH/g. When the acid value of the acryl-based binder resin is within the above range, resolution of the pixel pattern is improved.

The binder resin may be included in an amount of 1 wt % to 10 wt %, for example 3 wt % to 9 wt %, based on a total amount of the photosensitive resin composition. When the binder resin is included within the above range, the viscosity is appropriately maintained, and thus patternability, processability, and developability are improved when manufacturing a black matrix or a light blocking partition wall.

(B) Photopolymerizable Monomer

The photopolymerizable monomer may be mono-functional or multi-functional ester of (meth)acrylic acid including at least one ethylenically unsaturated double bond.

Since the acryl-based photopolymerizable monomer has the ethylenically unsaturated double bond, it is possible to form a pattern having excellent heat resistance, light resistance and chemical resistance by causing sufficient polymerization during exposure in the pattern formation process.

Specific examples of the photopolymerizable monomer may be ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaerythritol tetra(meth)acrylate, pentaerythritol hexa(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A epoxy(meth)acrylate, ethylene glycol monomethylether (meth)acrylate, trimethylol propane tri(meth)acrylate, tris(meth)acryloyloxyethyl phosphate, novolac epoxy (meth)acrylate, and the like.

Commercially available examples of the photopolymerizable monomer are as follows. The mono-functional (meth)acrylic acid ester may include Aronix M-101®, M-111®, M-114®, etc. of Toagosei Chemistry Industry Co., Ltd.; KAYARAD TC-110S®, KAYARAD TC-1205®, etc. of Nippon Kayaku Co., Ltd.; V-158®, V-2311®, etc. of Osaka Organic Chemical Ind., Ltd., and the like. Examples of a dysfunctional (meth)acrylic acid ester may include Aronix M-210®, Aronix M-210®, Aronix M-240®, Aronix M-6200®, etc. of Toagosei Chemistry Industry Co., Ltd.); KAYARAD HDDA®, KAYARAD HX-220®, KAYARAD R-604®, etc. of Nippon Kayaku Co., Ltd.; V-260®, V-312®, V-335 HP®, etc. of Osaka Organic Chemical Ind., Ltd., and the like. Examples of a tri-functional (meth)acrylic acid ester may Aronix M-309®, Aronix M-400®, Aronix M-405®, Aronix M-450®, Aronix M-710®, Aronix M-8030®, Aronix M-8060®, etc. of Toagosei Chemistry Industry Co., Ltd.; KAYARAD TMPTA®, KAYARAD DPCA-20®, KAYARAD-30®, KAYARAD-60®, KAYARAD-120, etc. of Nippon Kayaku Co., Ltd.; V-295®, V-300®, V-360®, V-GPT®, V-3PA®, V-400®, etc. of Osaka Organic Chemical Ind., Ltd., and the like. The above products may be used alone or in combination of two or more.

The photopolymerizable monomer may be treated with acid anhydride to improve developability.

The photopolymerizable monomer may be included in an amount of 0.5 wt % to 5 wt %, for example 0.5 wt % to 3 wt %, based on a total amount of the photosensitive resin composition. When the photopolymerizable monomer is included within the range, the photopolymerizable monomer is sufficiently cured during exposure in a pattern formation process, and may have improved reliability and developability by an alkali developing solution.

(C) Photopolymerization Initiator

The photopolymerization initiator may be an acetophenone compound, a benzophenone compound, a thioxanthone compound, a benzoin compound, a triazine compound, an oxime compound, or a combination thereof.

The acetophenone-based compound may include 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like.

The benzophenone-based compound may include benzophenone, benzoyl benzoate, benzoyl methyl benzoate, 4-phenyl benzophenone, hydroxy benzophenone, acrylated benzophenone, 4,4′-bis(dimethyl amino)benzophenone, 4,4′-bis(diethylamino)benzophenone, 4,4′-dimethylaminobenzophenone,4,4′-dichlorobenzophenone, 3,3′-dimethyl methoxybenzophenone, and the like.

The thioxanthone-based compound may include thioxanthone, 2-chlorothioxanthone, 2-methylthioxanthone, isopropyl thioxanthone, 2,4-diethyl thioxanthone, 2,4-diisopropyl thioxanthone, and the like.

The benzoin-based compound may include benzoin, benzoin methyl ether, benzoin ethyl ether, benzoin isopropyl ether, benzoin isobutyl ether, benzyldimethylketal, and the like.

The triazine-based compound may include 2,4,6-trichloro-s-triazine, 2-phenyl 4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloro methyl)-s-triazine, 2-biphenyl 4,6-bis(trichloro methyl)-s-triazine, bis(trichloromethyl)-6-styryl-s-triazine, 2-(naphthol-yl)-4,6-bis(trichloromethyl)-s-triazine, 2-(4-methoxynaphthol-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and the like.

The oxime-based compound may include an O-acyloxime-based compound, 2-(O-benzoyloxime)-1-[4-(phenylthio)phenyl]-1,2-octanedione, 1-(O-acetyloxime)-1-[9-ethyl-6-(2-methylbenzoyl)-9H-carbazol-3-yl]ethanone, O-ethoxycarbonyl-α-oxyamino-1-phenylpropan-1-one, 1-(3-cyclopentyl-1-(9-ethyl-6-(2-methylbenzoyl)-9H-carbazol-3-yl)propylideneaminooxy)ethanone, 2-(benzoyloxyimino)-3-cyclopentyl-1-(4-(phenylthio)phenyl)propan-1-one, and the like. Specific examples of the O-acyloxime-based compound may be 1,2-octanedione, 2-dimethylamino-2-(4-methylbenzyl)-1-(4-morpholin-4-yl-phenyl)-butan-1-one, 1-(4-phenyl sulfanyl phenyl)-butane-1,2-dione-2-oxime-O-benzoate, 1-(4-phenylsulfanyl phenyl)-octane-1,2-dione-2-oxime-O-benzoate, 1-(4-phenylsulfanyl phenyl)-octan-1-oneoxime-O-acetate and 1-(4-phenylsulfanyl phenyl)-butan-1-oneoxime-O-acetate, and the like.

The photosensitive resin composition according to an embodiment may include a mixture of an oxime compound and an acetophenone compound as a photopolymerization initiator. In this case, the oxime-based compound may be included in an amount higher than that of the acetophenone-based compound.

The photopolymerization initiator may further include a carbazole-based compound, a diketone-based compound, a sulfonium borate-based compound, a diazo-based compound, an imidazole-based compound, a biimidazole-based compound, a fluorene-based compound, and the like, in addition to the compounds.

The photopolymerization initiator may be included in an amount of 0.1 wt % to 5 wt %, for example 0.1 wt % to 3 wt % based on a total amount of the photosensitive resin composition. When the photopolymerization initiator is included within the above range, photopolymerization occurs sufficiently during exposure in the pattern formation process, and thus the sensitivity of the manufactured black matrix or light blocking partition wall is excellent.

(D) Black Inorganic Pigment

Considering compatibility with the aforementioned dispersion including the inorganic scatterer, in order to improve the light blocking properties and easily implement black, the black inorganic pigment constituting the dispersion including black inorganic pigment has a primary particle diameter of less than or equal to 45 nm. The dispersion including black inorganic pigment having a primary particle diameter of less than or equal to 45 nm is very suitable for use as a black colorant in the photosensitive resin composition according to an embodiment.

For example, the primary particle diameter of the black inorganic pigment may be less than or equal to 30 nm.

For example, the black inorganic pigment may include carbon black. For example, the black inorganic pigment may be carbon black.

For example, an amount of the dispersion including black inorganic pigment may be 3 times or more of an amount of the dispersion including an inorganic scatterer. In this case, since the optical density is higher, it is more advantageous to implement light blocking properties, and may be effective in reducing reflectance.

The black inorganic pigment may be used together with a dispersing agent. Specifically, the black inorganic pigment may be previously surface-treated with a dispersing agent, or may be used by adding a dispersing agent together with the black inorganic pigment when preparing the composition.

A non-ionic dispersing agent, an anionic dispersing agent, a cationic dispersing agent, and the like may be used as the dispersing agent. Specific examples of the dispersing agent include polyalkylene glycol and an ester thereof, polyoxyalkylene, a polyhydric alcohol ester alkylene oxide adduct, an alcohol alkylene oxide adduct, a sulfonic acid ester, a sulfonate, a carboxylic acid ester, a carboxylate, an alkyl amide alkylene oxide adduct, an alkyl amine, and the like, and these may be used alone or in combination of two or more.

For example, the commercially available products of the dispersing agent are DISPERBYK-101, DISPERBYK-130, DISPERBYK-140, DISPERBYK-160, DISPERBYK-161, DISPERBYK-162, DISPERBYK-163, DISPERBYK-164, DISPERBYK-165, DISPERBYK-166, DISPERBYK-170, DISPERBYK-171, DISPERBYK-182, DISPERBYK-2000, DISPERBYK-2001, and the like of BYK Co., Ltd.; EFKA-47, EFKA-47EA, EFKA-48, EFKA-49, EFKA-100, EFKA-400, EFKA-450, and the like of EFKA Chemicals Co.; Solsperse 5000, Solsperse 12000, Solsperse 13240, Solsperse 13940, Solsperse 17000, Solsperse 20000, Solsperse 24000GR, Solsperse 27000, Solsperse 28000, and the like of Zeneka Co.; or PB711, PB821, and the like of Ajinomoto Inc.

The dispersing agent may be included in an amount of 0.1 wt % to 15 wt % based on a total amount of the photosensitive resin composition. When the dispersing agent is included within the above range, stability, developability, and patternability are excellent in manufacturing the light blocking partition wall as dispersibility of the composition is improved.

The pigment may be used after pre-treatment using a water-soluble inorganic salt and a wetting agent. When the pigment is used after the pre-treatment, the average particle diameter of the pigment may become finer.

The pre-treatment may be performed by kneading the pigment with a water-soluble inorganic salt and a wetting agent and then, filtering and washing the knead pigment.

The kneading may be performed at a temperature ranging from about 40° C. to about 100° C., and the filtering and washing may be performed by filtering the pigment after washing away an inorganic salt with water and the like.

Examples of the water-soluble inorganic salt may be sodium chloride, potassium chloride, and the like, but are not limited thereto. The wetting agent may make the pigment to be uniformly mixed with the water-soluble inorganic salt uniformly and be pulverized. Examples of the wetting agent include alkylene glycol monoalkyl ethers such as ethylene glycol monoethylether, propylene glycol monomethylether, diethylene glycol monomethylether, and the like, and alcohols such as ethanol, isopropanol, butanol, hexanol, cyclohexanol, ethylene glycol, diethylene glycol, polyethylene glycol, glycerine polyethylene glycol, and the like. These may be used alone or in combination of two or more.

The pigment after the kneading may have an average particle diameter of 5 nm to 200 nm, for example 5 nm to 150 nm. When the average particle diameter of the pigment is within the above range, stability in the pigment dispersion is excellent, and a resolution of the pixel may not be deteriorated.

Specifically, the black inorganic pigment may be included in 15 wt % to 40 wt %, for example 20 wt % to 30 wt %, based on a total amount of the dispersion including black inorganic pigment.

The dispersion including black inorganic pigment may be included in an amount of 20 wt % to 40 wt %, for example 20 wt % to 30 wt % based on a total amount of the photosensitive resin composition. (The black inorganic pigment may be included in an amount of 5 wt % to 10 wt % based on a total amount of the photosensitive resin composition.) When the dispersion including black inorganic pigment is included within the above range, a black color realization effect and development performance may be improved.

(F) Solvent

The solvent may be a material that has compatibility with the aforementioned constituents and other additives described later, but do not react with them.

Examples of the solvent may be alcohols such as methanol, ethanol, and the like; ethers such as dichloroethylether, n-butylether, diisoamylether, methylphenylether, tetrahydrofuran, and the like; glycolethers such as ethylene glycolmonomethylether, ethylene glycolmonoethylether, ethylene glycoldimethylether, and the like; cellosolve acetates such as methylcellosolveacetate, ethylcellosolveacetate, diethylcellosolveacetate, and the like; carbitols such as methylethylcarbitol, diethylcarbitol, diethylene glycolmonomethylether, diethylene glycolmonoethylether, diethylene glycoldimethylether, diethylene glycolethylmethylether, diethylene glycoldiethylether, and the like; propylene glycolalkyletheracetates such as propylene glycolmethyletheracetate, propylene glycolpropyletheracetate, and the like; aromatic hydrocarbons such as toluene, xylene, and the like; ketones such as methylethylketone, cyclohexanone, 4-hydroxy-4-methyl-2-pentanone, methyl-n-propylketone, methyl-n-butylketone, methyl-n-amylketone, 2-heptanone, and the like; saturated aliphatic monocarboxylic acid alkyl esters such as ethyl acetate, n-butyl acetate, isobutyl acetate, and the like; lactate esters such as methyl lactate, ethyl lactate, and the like; oxyacetate alkyl esters such as methyl oxyacetate, ethyl oxyacetate, butyl oxyacetate, and the like; alkoxy acetate alkyl esters such as methyl methoxy acetate, ethyl methoxy acetate, butyl methoxy acetate, methyl ethoxy acetate, ethyl ethoxy acetate, and the like; 3-oxypropionate alkyl esters such as methyl 3-oxypropionate, ethyl 3-oxypropionate, and the like; 3-alkoxy propionate alkyl esters such as 3-methoxy methyl propionate, 3-methoxy ethyl propionate, 3-ethoxy ethyl propionate, 3-ethoxy methyl propionate, and the like; 2-oxypropionate alkyl esters such as 2-oxymethyl propionate, 2-oxyethyl propionate, propyl 2-oxypropionate, and the like; 2-alkoxypropionate alkylester such as 2-methoxymethyl propionate, 2-methoxyethyl propionate, 2-ethoxyethyl propionate, 2-ethoxymethyl propionate, and the like; 2-oxy-2-methylpropionate ester such as 2-oxy-2-methylmethyl propionate, 2-oxy-2-methylethyl propionate, and the like, monooxymonocarboxylic acid alkyl esters of alkyl 2-alkoxy-2-methylpropionate such as 2-methoxy-2-methylmethyl propionate, 2-ethoxy-2-methylethyl propionate, and the like; esters such as 2-hydroxyethyl propionate, 2-hydroxy-2-methyl ethyl propionate, hydroxyl ethyl acetate, 2-hydroxy-3-methyl ethyl butanoate, and the like; ketone acid esters such as ethyl pyruvate, and the like. In addition, a high boiling point solvent such as N-methylformamide, N,N-dimethyl formamide, N-methylformanilide, N-methylacetamide, N,N-dimethyl acetamide, N-methylpyrrolidone, dimethylsulfoxide, benzyl ethyl ether, dihexylether, acetylacetone, isophorone, caproic acid, caprylic acid, 1-octanol, 1-nonanol, benzylalcohol, benzyl acetate, ethyl benzoate, diethyl oxalate, diethyl maleate, γ-butyrolactone, 3-methylbenzoic acid, 3-methoxybutylacetate, ethylene carbonate, propylene carbonate, phenyl cellosolve acetate, and the like may be also used.

Considering compatibility and reactivity, ketones such as cyclohexanone, and the like; glycolethers such as ethylene glycolmonoethylether, ethylene glycoldimethylether, ethylene glycoldiethylether, diethylene glycolethylmethylether, and the like; ethylene glycolalkyletheracetates such as ethylcellosolveacetate, and the like; esters such as 2-hydroxyethyl propionate, and the like; carbitols such as diethylene glycolmonomethylether, and the like; propylene glycolalkyletheracetates such as propylene glycolmonomethyl ether acetate, propylene glycolpropyletheracetate, and the like, 3-methylbenzoic acid, 3-methoxybutylacetate, and the like may be desirably used.

The solvent may be included in a balance amount, for example 30 wt % to 70 wt %, for example 35 wt % to 65 wt %, for example 40 wt % to 60 wt % based on a total amount of the photosensitive resin composition. When the solvent is included within the range, the photosensitive resin composition may have an appropriate viscosity resulting in improvement of processibility of a black matrix or a light blocking partition wall.

(G) Dye

The photosensitive resin composition according to an embodiment may further include a dye. The dye may include a red dye, a yellow dye, a violet dye, or a combination thereof.

When a red dye, a yellow dye, a violet dye, or a combination thereof is additionally used, optical density may be further increased without impairing the pattern surface roughness and linearity.

Examples of the red dye may include a xanthene-based dye, an azo (pyridone-based, barbituric acid-based, etc.)-based dye, a disazo-based dye, an anthraquinone-based dye, and a methine-based dye, but are not limited thereto. In addition, it may be in a form of a laked pigment obtained by such a dye, an inorganic salt of an acidic dye having an acidic group such as sulfonic acid or carboxylic acid, a composed salt compound of an acidic dye and a nitrogen-containing compound, or a sulfonic acid amide compound of an acidic dye.

Examples of the yellow dye may include a quinoline-based dye, an azo-based (pyridone-based, barbituric acid-based metal complex-based, etc.) dye, a disazo-based dye, and a methine-based dye, but are not limited thereto.

Examples of the violet dye may include a xanthene-based oil-soluble dye such as C.I. Solvent Violet 2, C.I. Solvent Violet 10, and the like, a rhodamine-based oil-soluble dye such as C.I. Solvent Violet 2, a xanthene-based basic dye such as C.I. Basic Violet 10, and a xanthene-based acid dye such as C.I. Acid Violet 9, but are not limited thereto.

The dye may be included in an amount less than that of the dispersion including black inorganic pigment. For example, when the dye is included in an amount higher than that of the dispersion including black inorganic pigment, it may be undesirable because optical density is rather reduced due to a decrease in the relative amount of the dispersion including black inorganic pigment.

The dye may be included in a balance amount, for example 1 wt % to 10 wt %, for example 3 wt % to 8 wt % based on a total amount of the total amount of the photosensitive resin composition. When the dye is included within the above range, optical density of the photosensitive resin composition may be further increased, and low-reflection characteristics and excellent patternability may be achieved.

(H) Other Additives

Meanwhile, the photosensitive resin composition may further include an additive of malonic acid, 3-amino-1,2-propanediol, a silane-based coupling agent, a leveling agent, a surfactant, or a combination thereof.

The silane-based coupling agent may have a reactive substituent of a vinyl group, a carboxyl group, a methacryloxy group, an isocyanate group, an epoxy group, and the like, in order to improve close-contacting properties with a substrate.

Examples of the silane-based coupling agent may include trimethoxysilylbenzoic acid, γ methacryloxypropyltrimethoxysilane, vinyltriacetoxysilane, vinyltrimethoxysilane, γ isocyanatepropyltriethoxysilane, yglycidoxypropyltrimethoxysilane, β epoxycyclohexyl)ethyltrimethoxysilane, and the like, and these may be used alone or in a mixture of two or more.

The silane-based coupling agent may be included in an amount of 0.01 parts by weight to 10 parts by weight based on a total amount of the total amount of the photosensitive resin composition. When the silane-based coupling agent is included within the above range, close contacting property, storage capability, and the like are improved.

In addition, the photosensitive resin composition may further include a surfactant, such as a fluorine-based surfactant and/or a silicone-based surfactant, in order to improve coating properties and prevent defect generation, if necessary.

Examples of the fluorine-based surfactant may be a commercial fluorine-based surfactant such as BM-1000®, BM-1100®, and the like of BM Chemie Inc.; MEGAFACE F 142D®, MEGAFACE F 172®, MEGAFACE F 173®, MEGAFACE F 183®, MEGAFACE F 554®, and the like of Dainippon Ink Kagaku Kogyo Co., Ltd.; FULORAD FC-135®, FULORAD FC-170C®, FULORAD FC-430®, FULORAD FC-431®, and the like of SUMITOMO 3M Co., Ltd.; SURFLON S-112®, SURFLON S-113®, SURFLON S-131®, SURFLON S-141®, SURFLON 5-145®, and the like of Asahi Glass Co., Ltd.; SH-28PA®, SH-190®, SH-193®, SZ-6032®, SF-8428®, and the like of Toray Silicone Co., Ltd.

The silicone-based surfactant may be a commercial silicone-based surfactant such as BYK-307, BYK-333, BYK-361N, BYK-051, BYK-052, BYK-053, BYK-067A, BYK-077, BYK-301, BYK-322, BYK-325, and the like of BYK Chem.

The surfactant may be used in an amount of 0.001 parts by weight to 5 parts by weight based on a total amount of the total amount of the photosensitive resin composition. When the surfactant is included within the range, coating uniformity may be secured, a stain may not be produced, and wetting on an IZO substrate or a glass substrate is improved.

Furthermore, the photosensitive resin composition may include other additives such as an antioxidant, a stabilizer, and the like in a predetermined amount unless they deteriorate properties of the photosensitive resin composition.

The photosensitive resin composition according to an embodiment may be either positive or negative but should be negative to completely remove residues in regions where a pattern is exposed after exposing and developing the composition having light blocking properties.

Another embodiment provides photosensitive resin layer, for example a black matrix or a light blocking partition wall manufactured by exposure, development, and curing of the aforementioned photosensitive resin composition.

A method of manufacturing the photosensitive resin layer is as follows.

(1) Coating and Film Formation

The photosensitive resin composition is coated to have a desired thickness on a substrate such as a glass substrate or ITO substrate, and the like which undergoes a predetermined pretreatment, using a spin or slit coating method, a roll coating method, a screen-printing method, an applicator method, and the like, and is prebaked at 70° C. to 110° C. for 1 minute to 10 minutes to remove a solvent and to form a film.

(2) Exposure

After disposing a mask to form a necessary pattern on the obtained coating film, exposure is performed by irradiating an actinic ray of 200 nm to 500 nm. As a light source used for irradiation, a low-pressure mercury lamp, a high-pressure mercury lamp, an ultra-high pressure mercury lamp, a metal halide lamp, an argon gas laser, etc. may be used, and in some cases, an X-ray, an electron beam, and the like may be used.

Exposure process uses, for example, a light dose of 500 mJ/cm² or less (with a 365 nm sensor) when a high pressure mercury lamp is used. However, the light dose may vary depending on kinds of each component, its combination ratio, and a dry film thickness.

(3) Development

Only the exposed portions remain to form a pattern by dissolving and removing unnecessary portions using an alkaline aqueous solution as a developer.

(4) Post-Treatment

A post-treatment process of the image pattern obtained by development is performed to obtain a pattern having improved heat resistance, adhesion, chemical resistance, etc. For example, the image pattern obtained by development may be placed in a convection oven at 250° C. after development, followed by heating (post-baking) for 1 hour.

Another embodiment provides a display device including the photosensitive resin layer.

### MODE FOR INVENTION

Hereinafter, examples of the present invention are described. However, the following examples are only preferred examples of the present invention, and the present invention is not limited by the following examples.

### (Preparation of Photosensitive Resin Composition)

### Examples 1 to 3, Comparative Examples 1 to 3, and Reference Example 1

Photosensitive resin compositions according to Examples 1 to 3, Comparative Examples 1 to 3, and Reference Example 1 were prepared by mixing components in each composition shown in Table 1 and stirring the obtained mixture for 6 hours. Specifically, after precisely measuring an amount of a photopolymerization initiator and adding a solvent thereto, the mixture was sufficiently stirred, until the initiator was completely dissolved. Subsequently, a binder resin and a photopolymerizable monomer were sequentially added thereto and then, stirred again for 1 hour or so. Then, dispersion including an inorganic scatterer, and other additives were added thereto, dispersion including a black inorganic pigment was put therein, and finally, the entire composition was stirred for 2 hours or more to prepare a photosensitive resin composition.

TABLE 1
(unit: g)

| | | | | | Comp. | Comp. | Comp. | Ref. |
|---|---|---|---|---|---|---|---|---|
| | | Ex. 1 | Ex. 2 | Ex. 3 | Ex. 1 | Ex. 2 | Ex. 3 | Ex. 1 |
| (A) Binder | (A-1) | 2.512 | 1.825 | 2.512 | 6.129 | 6.322 | 2.512 | 2.874 |
| resin | (A-2) | 5.810 | 4.813 | 5.810 | — | — | 5.810 | 6.316 |
| (B) Photopolymerizable | | 1.028 | 1.058 | 1.028 | 1.339 | 1.028 | 11.028 | 1.481 |
| monomer | | | | | | | | |
| (C) Photopolymerization | (C-1) | 0.451 | 0.477 | 0.451 | 0.531 | 0.451 | 0.451 | 0.555 |
| initiator | (C-2) | 0.129 | 0.159 | 0.129 | 0.274 | 0.19 | 0.129 | 0.185 |
| (D) Dispersion | (D-1) | 21.528 | 21.165 | — | — | 21.528 | — | 17.776 |
| including black | (D-2) | — | — | 21.528 | — | — | — | — |
| inorganic pigment | (D-3) | — | — | — | 23.349 | — | — | — |
| | (D-4) | — | — | — | — | — | 21.528 | — |
| (E) Dispersionincluding | | 7.044 | 7.044 | 7.044 | — | 7.341 | 7.341 | 7.395 |
| an inorganic scatterer | | | | | | | | |
| (F) Solvent | | 61.020 | 56.833 | 61.020 | 68.191 | 63.020 | 61.020 | 63.230 |
| (G) Dye | (G-1) | — | 2.930 | — | — | — | — | — |
| | (G-2) | — | 3.513 | — | — | — | — | — |

| | | | | | | | |
|---|---|---|---|---|---|---|---|
| (H) Other additive | 0.181 | 0.181 | 0.181 | 0.186 | 0.181 | 0.181 | 0.187 |

(A) Binder Resin

(A-1) First Binder Resin

Cardo-based binder resin (A refractive index: 1.6, KBR101, Kyung-In Synthetic Corp.)

(A-2) Second Binder Resin

Acryl-based binder resin (A refractive index: 1.52, RY-25, Showa Denko K.K.)

(B) Photopolymerizable Monomer

Dipentaerythritol hexa(meth)acrylate (DPHA, Nippon Kayaku Co. Ltd.)

(C) Photopolymerization Initiator

(C-1) Oxime-based initiator (SPI-02, Samyang Corp.)

(C-2) Acetophenone-based initiator (IRG-369, BASF)

(D) Dispersion Including Black Inorganic Pigment

(D-1) Mill base including carbon black (A primary particle diameter of carbon black: 30 nm, Sakata Seed Corp.)

(D-2) Mill base including carbon black (A primary particle diameter of carbon black: 45 nm, Sakata Seed Corp.)

(D-3) Mill base including carbon black (A primary particle diameter of carbon black: 50 nm, Sakata Seed Corp.)

(D-4) Mill base including carbon black (A primary particle diameter of carbon black: 70 nm, Sakata Seed Corp.)

(E) Dispersion Including Inorganic Scatterer Dispersion including ZrO₂ (Mikuni Co.)

(F) Solvent Propylene glycol monomethyl ether acetate (PGMEA, Biryong Corp.)

(G) Dye

(G-1) Xanthene series red dye (RD-503, Kyung-In Synthetic Corp.)

(G-2) Azo-based Yellow dye (YDP-301, Kyung-In Synthetic Corp.)

(H) Other Additives

γ-glycidoxy propyl trimethoxysilane (S-510, Chisso Co.)

### (Evaluation)

### Evaluation of Reflectance

The photosensitive resin compositions according to Examples 1 to 3, Comparative Examples 1 to 3, and Reference Example 1 were respectively spin-coated to be about 1.3 μm thick on a glass substrate and pre-baked at about 100° C. for 90 seconds. Subsequently, the coated substrates were cooled down at room temperature for 60 seconds and irradiated by ultraviolet (UV) with 40 mJ/cm² by using an ultra high pressure mercury lamp to induce a photocurable reaction of a photosensitive portion. The exposed substrate was developed in a 0.043% KOH aqueous solution at room temperature in a spray method and then, washed with a pure solvent for 60 seconds. Subsequently, the washed substrate was dried at room temperature and then, post-baked in a 230° C. convection oven for 30 minutes to obtain a patterned specimen. Then, reflectance of the patterned specimen was measured with reference to 100% of reflectance of a Cr substrate by using an MCPD (Otsuka Electronics Co., Ltd.) equipment, and the results are shown in Table 2.

TABLE 2
(unit: %)

| | Reflectance (@ 550 nm, @1.2 μm) |
|---|---|
| Example 1 | 1.51 |
| Example 2 | 1.45 |
| Example 3 | 1.50 |
| Comparative Example 1 | 2.78 |
| Comparative Example 2 | 1.93 |
| Comparative Example 3 | 1.53 |
| Reference Example 1 | 1.38 |

### Evaluation of Optical Density

The photosensitive resin compositions according to Examples 1 to 3, Comparative Examples 1 to 3, and Reference Example 1 were respectively coated, exposed, developed, and post-baked to obtain patterned specimens, and then, optical density thereof per 1 μm was measured by using an OD meter, and the results are shown in Table 3.

TABLE 3

| | Optical Density (/1 μm) |
|---|---|
| Example 1 | 3.64 |
| Example 2 | 3.73 |
| Example 3 | 3.67 |
| Comparative Example 1 | 3.86 |
| Comparative Example 2 | 3.68 |
| Comparative Example 3 | 3.61 |
| Reference Example 1 | 2.61 |

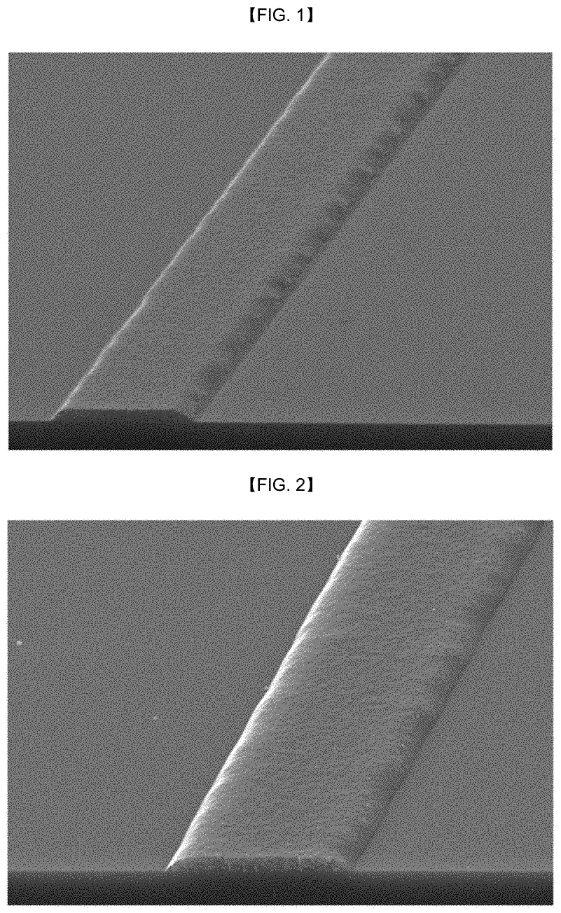

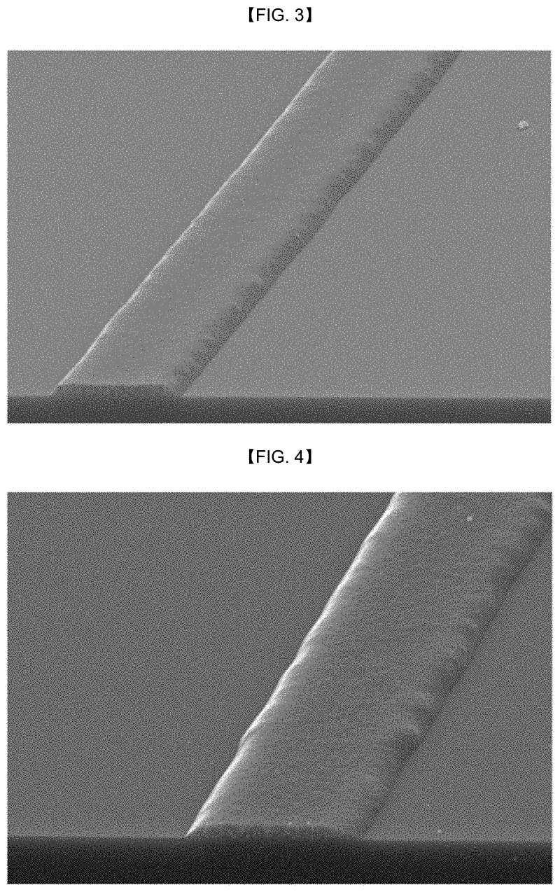

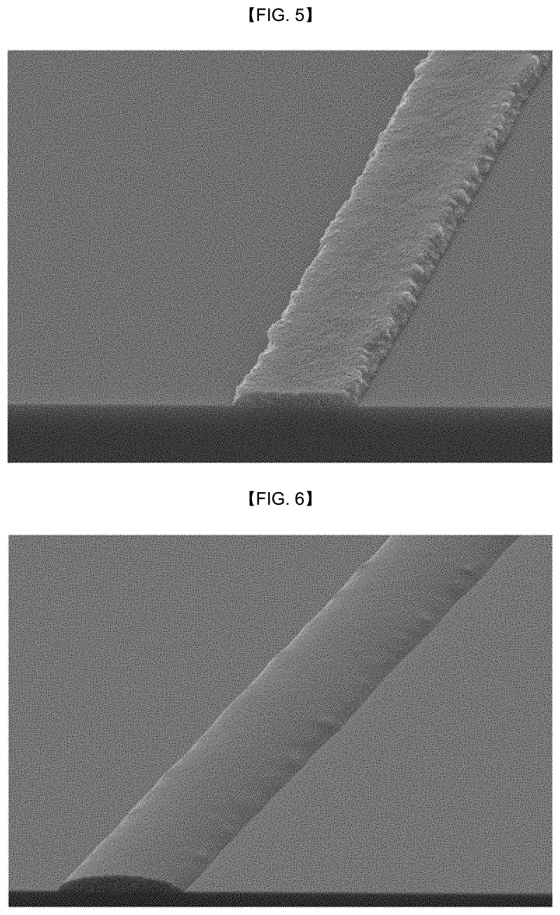

Referring to Tables 2 and 3 and FIGS. 1 to 6, the photosensitive resin composition according to an embodiment realized light blocking characteristics and low-reflection characteristics and simultaneously, exhibited excellent patternability.

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims. Therefore, the aforementioned embodiments should be understood to be exemplary but not limiting the present invention in any way.

1. A photosensitive resin composition, comprising:
(A) a binder resin including a first binder resin and a second binder resin,
(B) a photopolymerizable monomer,
(C) a photopolymerization initiator,
(D) a black inorganic pigment,
(E) an inorganic scatterer, and
(F) a solvent
wherein:
the first binder resin has a higher refractive index than a refractive index of the second binder resin,
the first binder resin is included in the photosensitive resin composition in an amount equal to or less than an amount of the second binder resin in the photosensitive resin composition, and
a primary particle diameter of the black inorganic pigment is less than or equal to 45 nm.

2. The photosensitive resin composition of claim 1, wherein the second binder resin has a refractive index of less than or equal to 1.55.

3. The photosensitive resin composition of claim 1, wherein:
the first binder resin is a cardo-based binder resin, and
the second binder resin is an acryl-based binder resin.

4. The photosensitive resin composition of claim 1, wherein the amount of the second binder resin is at least twice the amount of the first binder resin.

5. The photosensitive resin composition of claim 1, wherein the primary particle diameter of the black inorganic pigment is less than or equal to 30 nm.

6. The photosensitive resin composition of claim 1, wherein the black inorganic pigment includes carbon black.

7. The photosensitive resin composition of claim 6, wherein the inorganic scatterer includes SiO₂, TiO₂, ZrO₂, BaSO₃, or a combination thereof.

8. The photosensitive resin composition of claim 1, wherein:
both the black inorganic pigment and the inorganic scatterer are included in a form of a dispersion, and
an amount of the dispersion including black inorganic pigment is 3 times or more of an amount of the dispersion including the inorganic scatterer.

9. The photosensitive resin composition of claim 1, further comprising a dye.

10. The photosensitive resin composition of claim 9, wherein the dye includes a red dye, a yellow dye, a violet dye, or a combination thereof.

11. The photosensitive resin composition of claim 9, wherein:
the black inorganic pigment is included in a form of a dispersion, and
the dye is included in the photosensitive resin composition in an amount less than an amount of the dispersion including black inorganic pigment.

12. The photosensitive resin composition of claim 1, wherein the photosensitive resin composition includes, based on a total weight of the photosensitive resin composition,
1 wt % to 10 wt % of the (A) binder resin,
0.5 wt % to 5 wt % of the (B) photopolymerizable monomer,
0.1 wt % to 5 wt % of the (C) photopolymerization initiator,
5 wt % to 10 wt % of the (D) black inorganic pigment,
0.01 wt % to 0.1 wt % of the (E) inorganic scatterer, and
30 wt % to 70 wt % of the (F) solvent.

13. The photosensitive resin composition of claim 1, further comprising malonic acid, 3-amino-1,2-propanediol, a silane-based coupling agent, a leveling agent, surfactant, or a combination thereof.

14. A photosensitive resin layer manufactured using the photosensitive resin composition of claim 1.

15. The photosensitive resin layer of claim 14, wherein the photosensitive resin layer is a black matrix or a light blocking partition wall.

16. A display device comprising the photosensitive resin layer of claim 14.
